(19) United States
(12) Patent Application Publication
(10) Pub. No.: US 2024/0162406 A1
(43) Pub. Date: May 16, 2024

(54) DISPLAY PANEL AND MANUFACTURING METHOD THEREOF

(71) Applicant: AUO Corporation, Hsin-Chu (TW)

(72) Inventors: Chieh-Ming CHEN, Hsin-Chu (TW); Chou-Huan Yu, Hsin-Chu (TW); Bo-ru Jian, Hsin-Chu (TW); Ta-Wen Liao, Hsin-Chu (TW)

(21) Appl. No.: 18/480,645

(22) Filed: Oct. 4, 2023

(30) Foreign Application Priority Data
Nov. 11, 2022 (TW) 111143261

(51) Int. Cl. H01L 33/62; H01L 23/00; H01L 25/16; H01L 33/54

(52) U.S. Cl. CPC H01L 33/62; H01L 24/24; H01L 25/167; H01L 33/54; H01L 2224/24051; H01L 2224/24145; H01L 2224/245; H01L 2924/12041; H01L 2933/005; H01L 2933/0066

(57) ABSTRACT

A display panel including an array substrate, a light-emitting diode chip, a photosensitive material layer and a photosensitive material layer. The array substrate includes a first electrode pad and a second electrode pad adjacent to the first electrode pad. The light-emitting diode chip includes a first electrode and a second electrode at opposite sides of the light-emitting diode chip, and the first electrode is connected with the first electrode pad. The photosensitive material layer is over the array substrate and surrounds the light-emitting diode chip, in which the photosensitive material layer includes an opening exposing the second electrode pad, a sidewall of the opening has a first portion and a second portion, a slope of the first portion is greater than a slope of the second portion. The transparent conductive layer is over the photosensitive material layer and electrically connects the second electrode pad and the second electrode.

### CROSS-REFERENCE TO RELATED APPLICATION

This application claims priority to Taiwan Application Serial Number 111143261, filed Nov. 11, 2022, which is herein incorporated by reference in its entirety.

### BACKGROUND

### Field of Invention

The present disclosure relates to a display panel and a manufacturing method thereof.

### Description of Related Art

Light-emitting diode displays are a kind of common display nowadays. Generally, a mass transfer process is needed to transfer a large number of the light-emitting diodes to a certain carrier board when manufacturing the light-emitting diode display. Subsequently, a transparent conductive layer is formed over the light-emitting diodes and the carrier board to electrically connect electrodes of the light-emitting diodes and the electrodes over the carrier board. When the electrodes of the light-emitting diodes and the electrodes over the carrier board are not connected, the light-emitting diodes may not work.

### SUMMARY

Some embodiments in the present disclosure provide a display panel including an array substrate, a light-emitting diode chip, a first photosensitive material layer and a first photosensitive material layer. The array substrate includes a carrier board, a dielectric layer stack over the carrier board, a first electrode pad over the dielectric layer stack, and a second electrode pad over the dielectric layer stack and adjacent to the first electrode pad. The first electrode pad and the second electrode pad provide different potentials. The light-emitting diode chip includes a first electrode and a second electrode at opposite sides of the light-emitting diode chip, and the first electrode is connected with the first electrode pad. The first photosensitive material layer is over the array substrate and surrounds the light-emitting diode chip, in which the first photosensitive material layer includes an opening exposing the second electrode pad, a sidewall of the opening of the first photosensitive material layer has a first portion and a second portion, a first slope of the first portion of the sidewall of the opening of the first photosensitive material layer is greater than a second slope of the second portion of the sidewall of the opening of the first photosensitive material layer, and a vertical projection of the first portion of the sidewall of the opening of the first photosensitive material layer on the array substrate is smaller than a vertical projection of the second portion of the sidewall of the opening of the first photosensitive material layer on the array substrate. The first transparent conductive layer is over the first photosensitive material layer and electrically connects the second electrode pad and the second electrode.

In some embodiments, the display panel further includes a second photosensitive material layer over the first photosensitive material layer and surrounding the light-emitting diode chip, in which the second photosensitive material layer includes an opening exposing the second electrode pad and a portion of the first photosensitive material layer, a sidewall of the opening of the second photosensitive material layer has a first portion and a second portion, a first slope of the first portion of the sidewall of the opening of the second photosensitive material layer is greater than a second slope of the second portion of the sidewall of the opening of the second photosensitive material layer.

In some embodiments, the first slope of the first portion of the sidewall of the opening of the first photosensitive material layer is greater than 1, and the second slope of the first portion of the sidewall of the opening of the first photosensitive material layer is less than 1.

In some embodiments, the first slope of the first portion of the sidewall of the opening of the first photosensitive material layer is less than 1.2.

In some embodiments, the first slope of the first portion of the sidewall of the opening of the second photosensitive material layer is greater than 1, and the second slope of the first portion of the sidewall of the opening of the second photosensitive material layer is less than 1.

In some embodiments, the first slope of the first portion of the sidewall of the opening of the second photosensitive material layer is less than 1.2.

In some embodiments, the sidewall of the opening of the first photosensitive material layer further has a third portion and a fourth portion, the second slope of the second portion and a fourth slope of the fourth portion of the sidewall of the opening of the first photosensitive material layer are less than a third slope of the third portion of the sidewall of the opening of the first photosensitive material layer.

In some embodiments, the sidewall of the opening of the second photosensitive material layer further has a third portion and a fourth portion, the second slope of the second portion and a fourth slope of the fourth portion of the sidewall of the opening of the second photosensitive material layer are less than a third slope of the third portion of the sidewall of the opening of the second photosensitive material layer.

Some embodiments in the present disclosure provide a display panel, including an array substrate, a light-emitting diode chip, a first photosensitive material layer, a first transparent conductive layer, a second photosensitive material layer and a second transparent conductive layer. The array substrate includes a carrier board, an active component, a dielectric layer stack, a first electrode pad and a second electrode pad. The active component is over the carrier board. The dielectric layer stack is over the active component and the carrier board. The first electrode pad is over the dielectric layer stack and connected with the active component. The second electrode pad is over the dielectric layer stack and adjacent to the first electrode pad. The light-emitting diode chip includes a first electrode and a second electrode at opposite sides of the light-emitting diode chip, and the first electrode is connected with the first electrode pad. The first photosensitive material layer is over the array substrate and surrounds the light-emitting diode chip, in which the first photosensitive material layer includes an opening exposing the second electrode pad. The first transparent conductive layer is over the first photosensitive material layer and in contact with the second electrode pad. The second photosensitive material layer is over the first photosensitive material layer and surrounds the light-emitting diode chip, in which the second photosensitive material layer includes an opening exposing the second electrode pad and a portion of the first photosensitive material layer. The second transparent conductive layer is over the second photosensitive material layer and the first transparent conductive layer.

In some embodiments, the display panel further includes a nitride layer between the first photosensitive material layer and the first transparent conductive layer.

In some embodiments, the first transparent conductive layer is between the first photosensitive material layer and the second photosensitive material layer.

In some embodiments, a sidewall of the opening of the first photosensitive material layer has a first portion and a second portion, the first portion is closer to the second electrode pad, the second portion is farther away from the second electrode pad, a first slope of the first portion of the sidewall of the opening of the first photosensitive material layer is greater than a second slope of the second portion of the sidewall of the opening of the first photosensitive material layer.

In some embodiments, the sidewall of the opening of the first photosensitive material layer further has a third portion and a fourth portion, the third portion is connected with the second portion, the third portion is connected with the third portion, a third slope of the third portion of the sidewall of the opening of the first photosensitive material layer is greater than the second slope of the second portion of the sidewall of the opening of the first photosensitive material layer and a fourth slope of the fourth portion of the sidewall of the opening of the first photosensitive material layer.

In some embodiments, the second photosensitive material layer comprises an opening exposing the second electrode pad and a portion of the first photosensitive material layer, a sidewall of the opening of the second photosensitive material layer has a first portion and a second portion, a first slope of the first portion of the sidewall of the opening of the second photosensitive material layer is greater than a second slope of the second portion of the sidewall of the opening of the second photosensitive material layer.

Some embodiments in the present disclosure provide a method of manufacturing a display panel, including disposing a light-emitting diode chip over a array substrate, in which the light-emitting diode chip includes a first electrode and a second electrode at opposite sides of the light-emitting diode chip, and the first electrode is connected with a first electrode pad of the array substrate. A first photosensitive material layer is formed over the array substrate, and the first photosensitive material layer surrounds the light-emitting diode chip. The first photosensitive material layer is exposed by a first slit tone photomask. The first photosensitive material layer is developed, such that the first photosensitive material layer includes an opening exposing a second electrode pad of the array substrate, a sidewall of the opening of the first photosensitive material layer has a first portion and a second portion, a first slope of the first portion of the sidewall of the opening of the first photosensitive material layer is greater than a second slope of the second portion of the sidewall of the opening of the first photosensitive material layer. A first transparent conductive layer is formed over the first photosensitive material layer, the first transparent conductive layer electrically connected with the second electrode of the light-emitting diode chip and the second electrode pad of the array substrate.

In some embodiments, exposing the first photosensitive material layer by the first slit tone photomask includes adjusting distances between slits of the first slit tone photomask.

In some embodiments, exposing the first photosensitive material layer by the first slit tone photomask includes adjusting sizes of slits of the first slit tone photomask.

In some embodiments, the method further includes after forming the first transparent conductive layer, forming a second photosensitive material layer over the first transparent conductive layer and surrounding the light-emitting diode chip. The second photosensitive material layer is exposed by a second slit tone photomask. The second photosensitive material layer is developed, such that the second photosensitive material layer includes an opening exposing the second electrode pad, a sidewall of the opening of the second photosensitive material layer has a first portion and a second portion, a first slope of the first portion of the sidewall of the opening of the second photosensitive material layer is greater than a second slope of the second portion of the sidewall of the opening of the second photosensitive material layer. A second transparent conductive layer is formed over the second photosensitive material layer, the second transparent conductive layer electrically is connected with the second electrode of the light-emitting diode chip and the second electrode pad of the array substrate.

In some embodiments, exposing the second photosensitive material layer by the second slit tone photomask comprising adjusting distances between slits of the second slit tone photomask.

In some embodiments, exposing the second photosensitive material layer by the second slit tone photomask comprising adjusting sizes of slits of the second slit tone photomask.

Some embodiments of the present disclosure are used to reduce the risk of fracture of transparent conductive layers of display panels. Specifically, the risk of the fracture of the transparent conductive layers is reduced by reducing the slope of the transparent conductive layers. As a result, the possibility of failure of the light-emitting diode chips due to the fracture of the transparent conductive layers may be reduced.

It is to be understood that both the foregoing general description and the following detailed description are by examples, and are intended to provide further explanation of the invention as claimed. It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 illustrates a cross-section of a display panel in some embodiments of the present disclosure.

FIG. 2 illustrates a profile of the first portion and the second portion of the opening of the first photosensitive material layer.

FIG. 3 illustrates a cross-section of a display panel in some other embodiments of the present disclosure.

FIG. 4 illustrates a profile of the first portion and the second portion of the opening of the second photosensitive material layer.

FIGS. 5-8 illustrate cross-section views of a manufacturing method of the display panel in some embodiments of the present disclosure.

FIGS. 9-11 illustrate cross-section views of a manufacturing method of the display panel in some other embodiments of the present disclosure.

FIG. 12 illustrates a cross-section of a display panel in some other embodiments of the present disclosure.

FIG. 13 illustrates a profile of the first photosensitive material layer of the display panel in region M in FIG. 12.

FIG. 14 illustrates a cross-section of a display panel in some other embodiments of the present disclosure.

FIG. 15 illustrates a profile of the first photosensitive material layer and the second photosensitive material layer of the display panel in region N in FIG. 14.

FIG. 16 illustrates a cross-section view of the display panel in some other embodiments of the present disclosure.

FIG. 17 illustrates a cross-section view of the display panel in some other embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figs. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the present disclosure are used to reduce the risk of fracture of transparent conductive layers of display panels. Specifically, the risk of the fracture of the transparent conductive layers is reduced by reducing the slope of the transparent conductive layers. As a result, the possibility of failure of the light-emitting diode chips due to the fracture of the transparent conductive layers may be reduced.

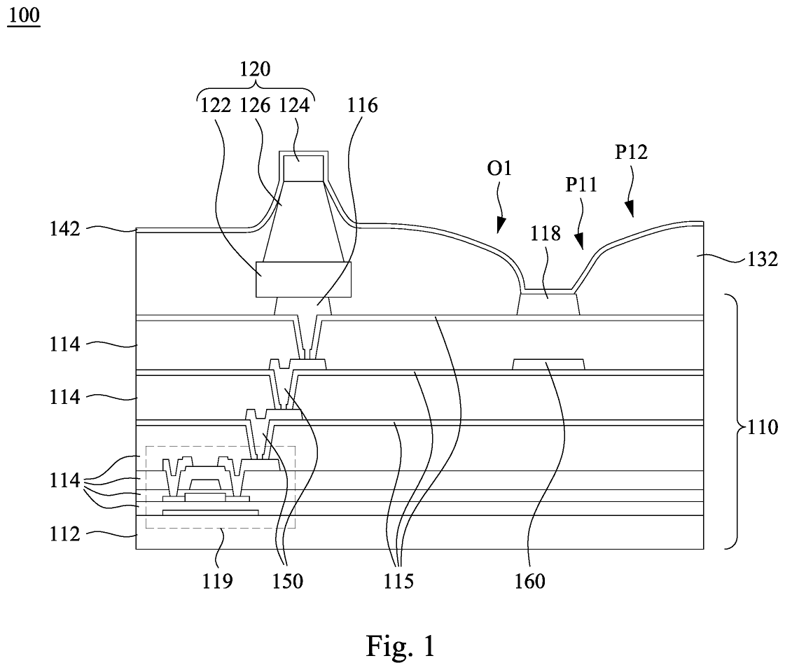

FIG. 1 illustrates a cross-section of a display panel 100 in some embodiments of the present disclosure. The display panel 100 includes an array substrate 110, a light-emitting diode chip 120, a first photosensitive material layer 132 and a first transparent conductive layer 142.

The array substrate 110 is a substrate including drive components. For example, the array substrate 110 includes a carrier board 112, a dielectric layer stack 114, a first electrode pad 116 and a second electrode pad 118. The dielectric layer stack 114 is over the carrier board 112. The first electrode pad 116 is over the dielectric layer stack 114. The second electrode pad 118 is over the dielectric layer stack 114 and adjacent to the first electrode pad 116, and the first electrode pad 116 and the second electrode pad 118 provide different potentials. In some embodiments, as shown in FIG. 1, the array substrate 110 may include active component 119, such as thin film transistor (TFT). In some other embodiments, the array substrate 110 may include other drive components, such as microchips, or the active components may not at the location shown in FIG. 1. For example, the active components may be below the carrier board 112 and drive the display panel 100 by double-sided wiring. In some embodiments, the array substrate 110 includes dielectric layers 115 between the dielectric layer stack 114, and the dielectric layers 115 may be made of silicon nitride. In some embodiments, the dielectric layer stack 114 may be made of dielectric material, such as silicon oxide. The first electrode pad 116 and the second electrode pad 118 may be made of conductive material, such as metal.

The light-emitting diode chip 120 includes a first electrode 122 and a second electrode 124 at opposite sides of the light-emitting diode chip 120, and the first electrode 122 is electrically connected with the first electrode pad 116. The second electrode 124 is electrically connected with the second electrode pad 118. Specifically, the first electrode 122 and the second electrode 124 may at the opposite sides of the semiconductor layer 126 of the light-emitting diode chip 120. The light-emitting diode chip 120 is disposed over the first electrode pad 116, such that the first electrode 122 is directly in contact with the first electrode pad 116. In some embodiments, the first electrode 122 and the second electrode 124 may be made of metal, such as nickel, tin, gold. Specifically, the array substrate 110 may further include first vias 150 and second vias 160. The first vias 150 and the second vias 160 are in the dielectric layer stack 114. The first vias 150 are electrically connected with the active component 119 and the first electrode 122 of the light-emitting diode chip 120. The second vias 160 are electrically connected with a ground electrode (not illustrated) and the second electrode 124 of the light-emitting diode chip 120. It is noted that although the second vias 160 on the different dielectric layer stack 114 are not connected with each other in FIG. 1, the second vias 160 on the different dielectric layer stack 114 are still connected with each other in the cross-section different from the cross-section shown in FIG. 1.

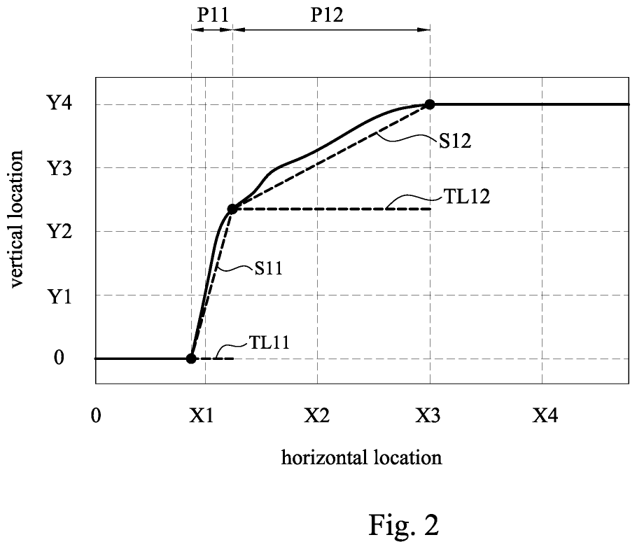

The first photosensitive material layer 132 is over the array substrate 110 and surrounds the light-emitting diode chip 120. The first photosensitive material layer 132 includes an opening O1 exposing the second electrode pad 118. A sidewall of the opening O1 of the first photosensitive material layer 132 has a first portion P11 and a second portion P12. The first portion P11 is closer to the second electrode pad 118, the second portion P12 is farther away from the second electrode pad 118, and the first portion P11 is connected with the second portion P12. FIG. 2 illustrates a profile of the first portion P11 and the second portion P12 of the opening O1 of the first photosensitive material layer 132. A first slope S11 of the first portion P11 of the sidewall of the opening O1 of the first photosensitive material layer 132 is greater than a second slope S12 of the second portion P12 of the sidewall of the opening O1 of the first photosensitive material layer 132, and a vertical projection TL11 of the first portion P11 of the sidewall of the opening O1 of the first photosensitive material layer 132 on the array substrate 110 is smaller than a vertical projection TL12 of the second portion P12 of the sidewall of the opening O1 of the first photosensitive material layer 132 on the array substrate 110. That is, the first portion P11 and the second portion P12 form a staircase structure. As a result, the slope of the first photosensitive material layer 132 may be reduced, such that the slope of the first transparent conductive layer 142 subsequently formed on the first photosensitive material layer 132 may be reduced. Therefore, the possibility of fracture of the first transparent conductive layer 142 may be reduced. In some embodiments, the first slope S11 is greater than 1, and the second slope S12 is less than 1. In some embodiments, the first slope S11 is not greater than 1.2. If the first slope S11 and the second slope S12 are not within the range disclosed above, the slope of the first photosensitive material layer 132 is significant, and the first transparent conductive layer 142 tends to fracture.

Back to FIG. 1, the first transparent conductive layer 142 is over the first photosensitive material layer 132 and electrically connects the second electrode pad 118 and the second electrode 124. The first transparent conductive layer 142 may be made of transparent conductive material, such as indium tin oxide (ITO). The first transparent conductive layer 142 conformally covers the light-emitting diode chip 120, the first photosensitive material layer 132 and the second electrode pad 118, such that the first transparent conductive layer 142 can electrically connect the second electrode pad 118 and the second electrode 124. Since the first transparent conductive layer 142 conformally covers the first photosensitive material layer 132, the profile of the first photosensitive material layer 132 may determine the slope of the first transparent conductive layer 142. When the slope and vertical projection of the first photosensitive material layer 132 are shown as FIG. 2, the first transparent conductive layer 142 is less likely to fracture, and the light-emitting diode chip 120 is more likely to work.

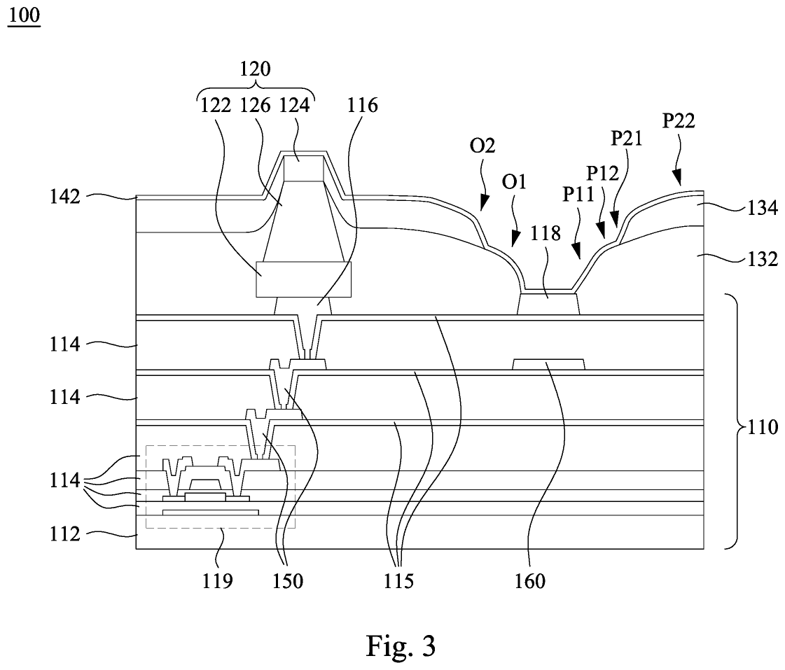

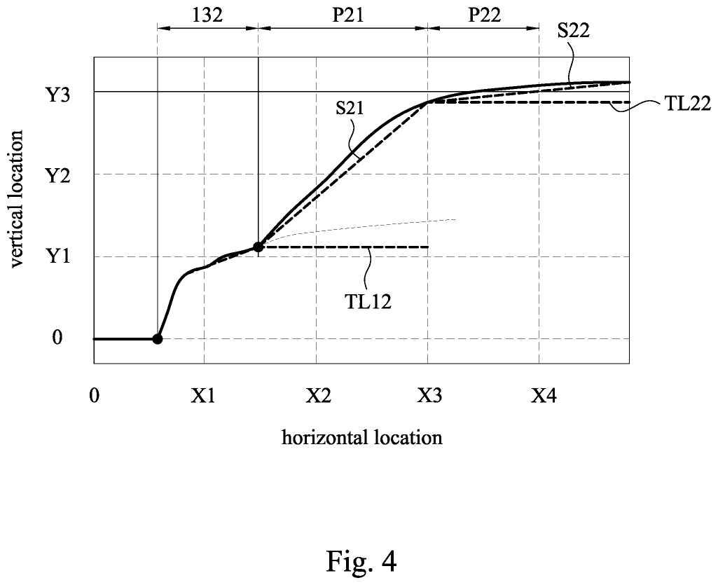

FIG. 3 illustrates a cross-section view of the display panel 100 in some other embodiments of the present disclosure. The display panel 100 further includes a second photosensitive material layer 134. The second photosensitive material layer 134 is over the first photosensitive material layer 132 and surrounds the light-emitting diode chip 120. The second photosensitive material layer 134 includes an opening O2 exposing the second electrode pad 118 and a portion of the first photosensitive material layer 132. A sidewall of the opening O2 of the second photosensitive material layer 134 has a first portion P21 and a second portion P22. The first portion P21 is closer to the second electrode pad 118, the second portion P22 is farther away from the second electrode pad 118, and the first portion P21 is connected with the second portion P22. FIG. 4 illustrates a profile of the first portion P21 and the second portion P22 of the opening O2 of the second photosensitive material layer 134. A first slope S21 of the first portion P21 of the sidewall of the opening O2 of the second photosensitive material layer 134 is greater than a second slope S22 of the second portion P22 of the sidewall of the opening O2 of the second photosensitive material layer 134, and a vertical projection TL21 of the first portion P21 of the sidewall of the opening O2 of the second photosensitive material layer 134 on the array substrate 110 is smaller than a vertical projection TL22 of the second portion P22 of the sidewall of the opening O2 of the second photosensitive material layer 134 on the array substrate 110. That is, the first portion P21 and the second portion P22 form a staircase structure. As a result, the slope of the second photosensitive material layer 134 may be reduced, such that the slope of the first transparent conductive layer 142 subsequently formed on the first photosensitive material layer 132 may be reduced. Therefore, the possibility of fracture of the first transparent conductive layer 142 may be reduced. In some embodiments, the first slope S21 is greater than 1, and the second slope S22 is less than 1. In some embodiments, the first slope S21 is not greater than 1.2. If the first slope S21 and the second slope S22 are not within the range disclosed above, the slope of the second photosensitive material layer 134 is significant, and the first transparent conductive layer 142 tends to fracture.

Back to FIG. 3, the first transparent conductive layer 142 is over the first photosensitive material layer 132 and the second photosensitive material layer 134, and electrically connects the second electrode pad 118 and the second electrode 124. Since the first transparent conductive layer 142 conformally covers the first photosensitive material layer 132 and the second photosensitive material layer 134, the profile of the first photosensitive material layer 132 and the second photosensitive material layer 134 can determine the slope of the first transparent conductive layer 142. When the slope and the vertical projection of the first photosensitive material layer 132 and the second photosensitive material layer 134 are shown as FIG. 4, the first transparent conductive layer 142 is less likely to fracture, and the light-emitting diode chip 120 is more likely to work.

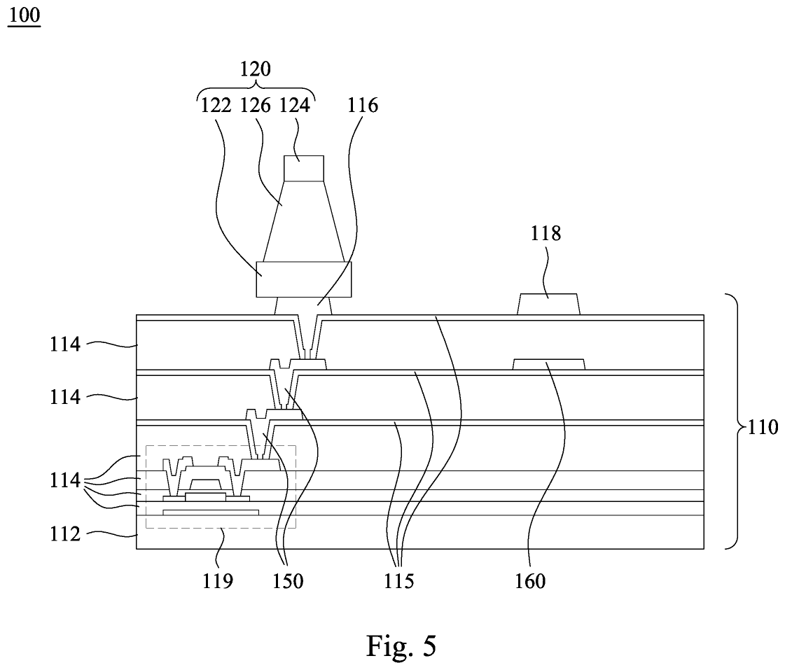

FIGS. 5-8 illustrate cross-section views of a manufacturing method of the display panel 100 (such as display panel 100 in FIG. 1). Referring to FIG. 5, the light-emitting diode chip 120 is disposed over the array substrate 110. The light-emitting diode chip 120 includes a first electrode 122 and a second electrode 124 at opposite sides of the light-emitting diode chip 120, and the first electrode 122 is connected with the first electrode pad 116 of the array substrate 110. Specifically, the light-emitting diode chip 120 is transferred to the array substrate 110 by mass transfer, and the first electrode 122 of the light-emitting diode chip 120 is disposed over the first electrode pad 116 of the array substrate 110.

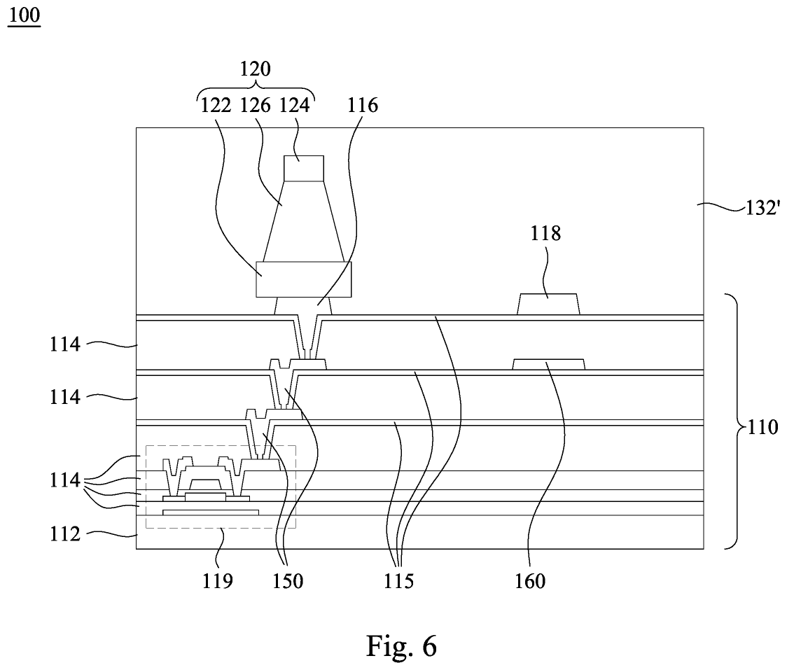

Referring to FIG. 6, a first photosensitive material layer 132′ is formed over the array substrate 110, and the first photosensitive material layer 132′ surrounds the light-emitting diode chip 120. The first photosensitive material layer 132′ may be made of the material that can be patterned by photolithography process. In some embodiments, the first photosensitive material layer 132′ may be made of organic material, such as acrylic resin. In some embodiments, the first photosensitive material layer 132′ may contain sensitizer, solvent (such as propylene glycol methyl ether acetate (PGMEA)) and additive (such as adhesion promoting agent, hardening accelerator or surfactant). In some embodiments, the first photosensitive material layer 132′ may cover the second electrode 124 of the light-emitting diode chip 120. In some embodiments, the first photosensitive material layer 132′ may be formed by spin coating process.

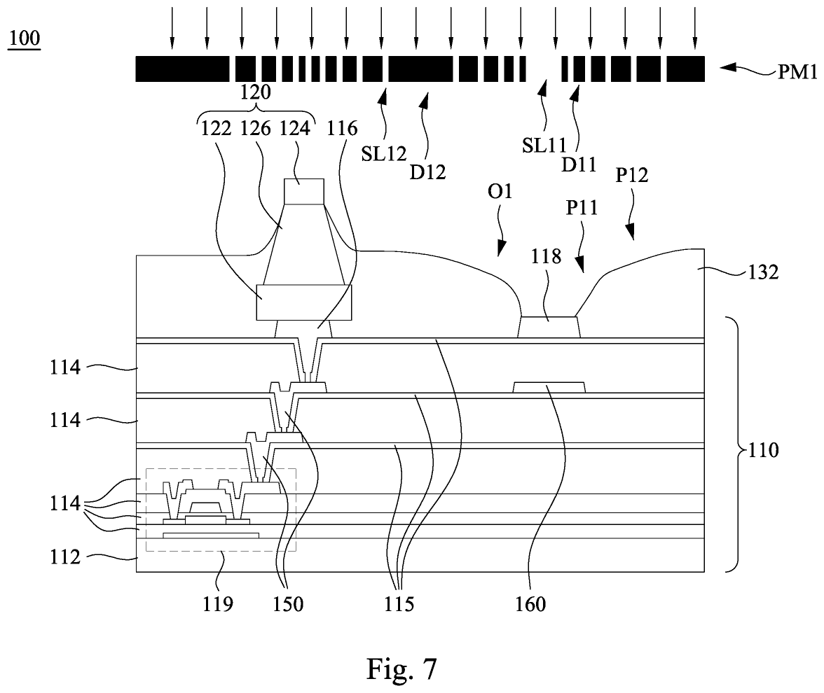

Referring to FIG. 7, the first photosensitive material layer 132′ is exposed by a first slit tone photomask PM1, and the first photosensitive material layer 132′ is developed, such that the first photosensitive material layer 132′ includes the opening O1 exposing the second electrode pad 118. The first photosensitive material layer 132′ after development becomes the first photosensitive material layer 132. Specifically, exposing the first photosensitive material layer 132′ by the first slit tone photomask PM1 includes adjusting distances between slits of the first slit tone photomask PM1 to change the depth of the exposed material of the first photosensitive material layer 132′. For example, a smaller distance D11 makes the first photosensitive material layer 132′ receive more exposure per unit length, and the exposure depth of the first photosensitive material layer 132′ is deeper. A larger distance D12 makes the first photosensitive material layer 132′ receive less exposure per unit length, and the exposure depth of the first photosensitive material layer 132′ is shallower. In addition, exposing the first photosensitive material layer 132′ by the first slit tone photomask PM1 may also include adjusting the size of the slits of the first slit tone photomask PM1. For example, larger width of the slit SL11 makes the first photosensitive material layer 132′ receive more exposure. Smaller width of the slit SL12 makes the first photosensitive material layer 132′ receive less exposure. In some embodiments, the slit SL11 over the second electrode pad 118 is larger, and the distance D11 between the slits over the second electrode pad 118 is smaller. The slit SL12 over the first electrode pad 116 is smaller, and the distance D12 between the slits over the first electrode pad 116 is larger. After exposing the first photosensitive material layer 132′, the first photosensitive material layer 132′ is developed, such that the first photosensitive material layer 132 includes the opening O1 exposing the second electrode pad 118. The sidewall of the opening O1 of the first photosensitive material layer 132 has the first portion P11 and the second portion P12. The first slope S11 of the first portion P11 of the sidewall of the opening O1 of the first photosensitive material layer 132 is greater than the second slope S12 of the second portion P12 of the sidewall of the opening O1 of the first photosensitive material layer 132 (see FIG. 2). As a result, the profile of the first photosensitive material layer 132 may be adjusted by adjusting the size of the slit and the distance between the slits of the photomask.

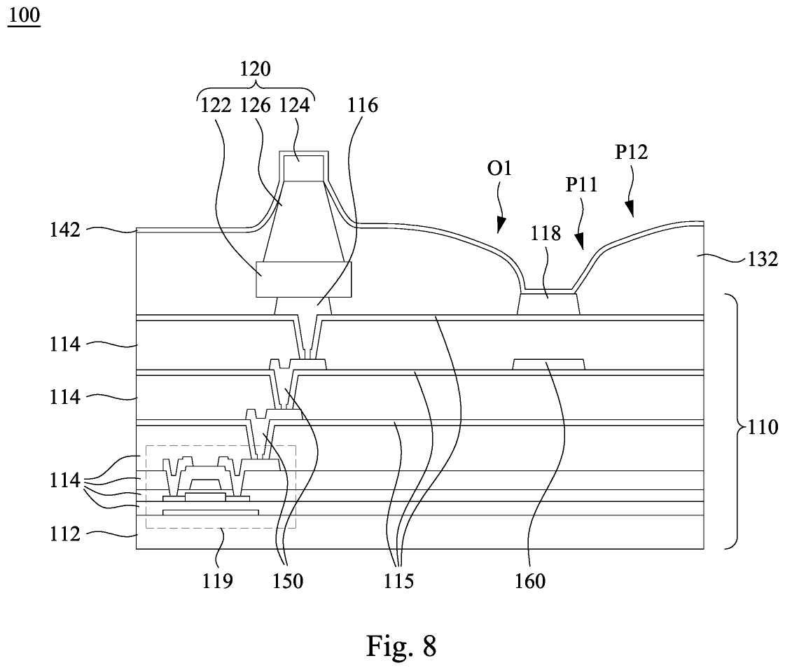

Referring to FIG. 8, the first transparent conductive layer 142 is formed over the first photosensitive material layer 132. The first transparent conductive layer 142 electrically connects the second electrode 124 of the light-emitting diode chip 120 and the second electrode pad 118 of the array substrate 110. As a result, the first electrode 122 and the second electrode 124 of the light-emitting diode chip 120 are respectively electrically connected with the first electrode pad 116 and the second electrode pad 118 of the array substrate 110.

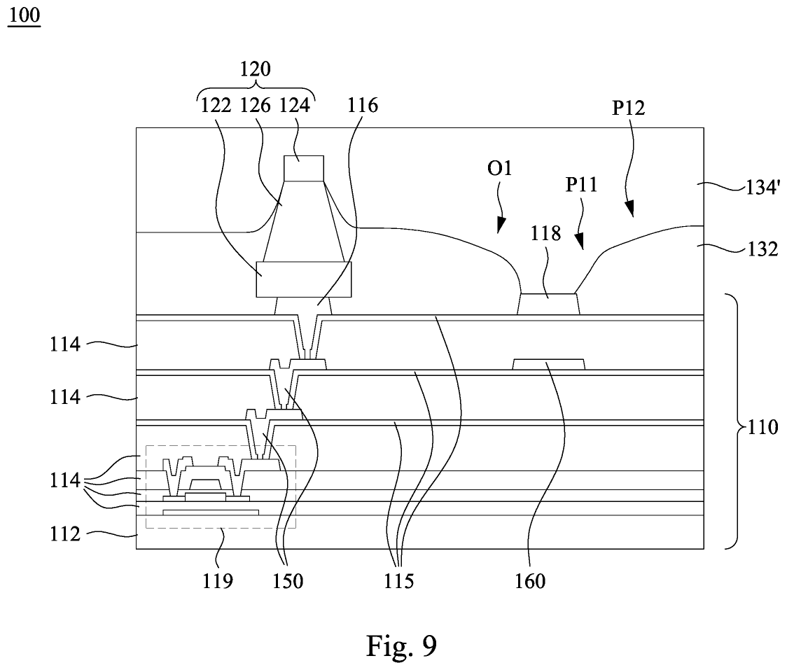

FIGS. 9-11 illustrate cross-section views of a manufacturing method of the display panel 100 (such as display panel 100 in FIG. 3) in some other embodiments. Specifically, after the process of FIG. 7, the process in FIGS. 9-11 are continued to form the display panel 100 in FIG. 3.

Referring to FIG. 9, a second photosensitive material layer 134′ is formed over the first photosensitive material layer 132 and the array substrate 110, and the second photosensitive material layer 134′ surrounds the light-emitting diode chip 120. The second photosensitive material layer 134′ may be made of the similar material to or the same material as the first photosensitive material layer 132′, and the manufacturing process of the second photosensitive material layer 134′ may be similar to the manufacturing process of the first photosensitive material layer 132′. Therefore, the detailed description related to the second photosensitive material layer 134′ is not described herein. In some embodiments, the second photosensitive material layer 134′ may cover the second electrode 124 of the light-emitting diode chip 120.

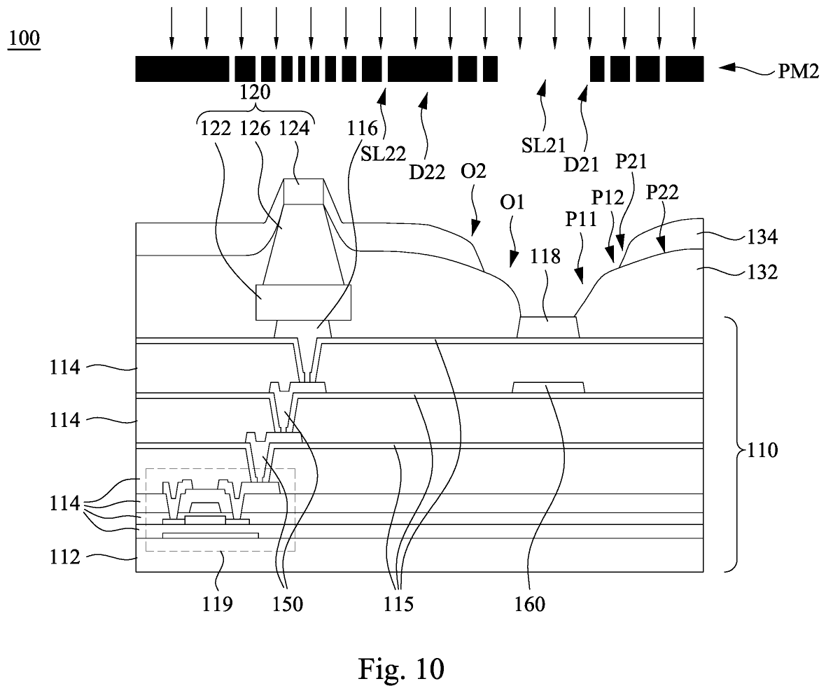

Referring to FIG. 10, the second photosensitive material layer 134′ is exposed by a second slit tone photomask PM2, and the second photosensitive material layer 134′ is developed, such that the second photosensitive material layer 134′ includes the opening O2 exposing the second electrode pad 118. The second photosensitive material layer 134′ after development becomes the second photosensitive material layer 134. Specifically, exposing the second photosensitive material layer 134′ by the second slit tone photomask PM2 includes adjusting distances between slits of the second slit tone photomask PM2 to change the depth of the exposed material of the second photosensitive material layer 134′. For example, a smaller distance D21 makes the second photosensitive material layer 134′ receive more exposure per unit length, and the exposure depth of the second photosensitive material layer 134′ is deeper. A larger distance D22 makes the second photosensitive material layer 134′ receive less exposure per unit length, and the exposure depth of the second photosensitive material layer 134′ is shallower. In addition, exposing the second photosensitive material layer 134′ by the second slit tone photomask PM2 may also include adjusting the size of the slits of the second slit tone photomask PM2. For example, larger width of the slit SL21 makes the second photosensitive material layer 134′ receive more exposure. Smaller width of the slit SL22 makes the second photosensitive material layer 134′ receive less exposure. In some embodiments, the slit SL21 over the second electrode pad 118 is larger, and the distance D21 between the slits over the second electrode pad 118 is smaller. The slit SL22 over the first electrode pad 116 is smaller, and the distance D22 between the slits over the first electrode pad 116 is larger. After exposing the second photosensitive material layer 134′, the second photosensitive material layer 134′ is developed, such that the second photosensitive material layer 134 includes the opening O2 exposing the second electrode pad 118. The sidewall of the opening O2 of the second photosensitive material layer 134 has the first portion P21 and the second portion P22. The first slope S21 of the first portion P21 of the sidewall of the opening O2 of the second photosensitive material layer 134 is greater than the second slope S22 of the second portion P22 of the sidewall of the opening O2 of the second photosensitive material layer 134 (see FIG. 4). As a result, the profile of the second photosensitive material layer 134 may be adjusted by adjusting the size of the slit and the distance between the slits of the photomask.

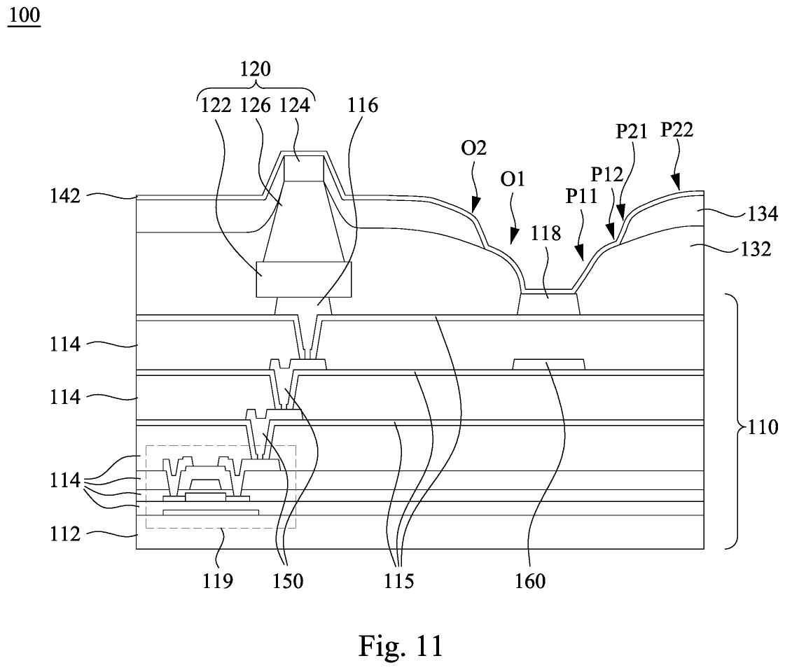

Referring to FIG. 11, the first transparent conductive layer 142 is formed over the first photosensitive material layer 132 and the second photosensitive material layer 134. The first transparent conductive layer 142 electrically connects the second electrode 124 of the light-emitting diode chip 120 and the second electrode pad 118 of the array substrate 110. As a result, the first electrode 122 and the second electrode 124 of the light-emitting diode chip 120 are respectively electrically connected with the first electrode pad 116 and the second electrode pad 118 of the array substrate 110.

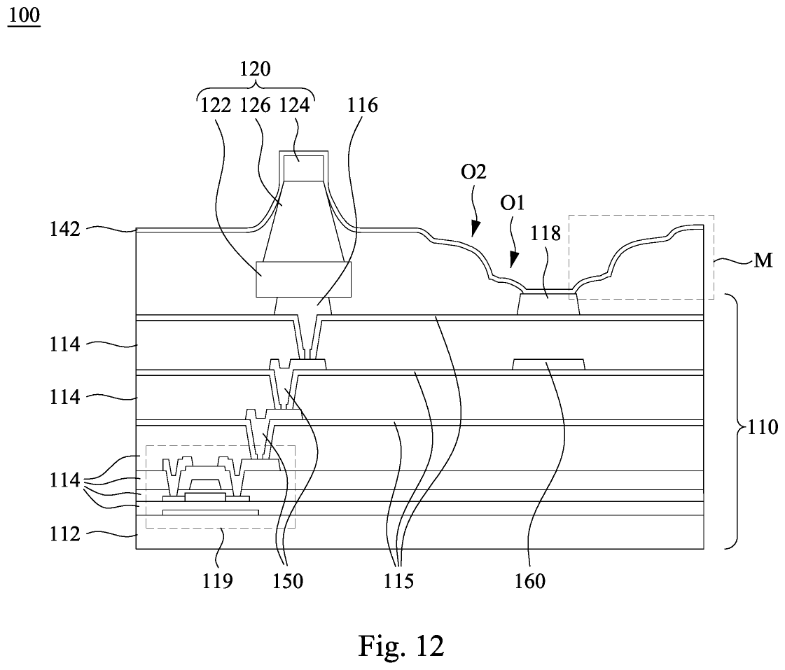

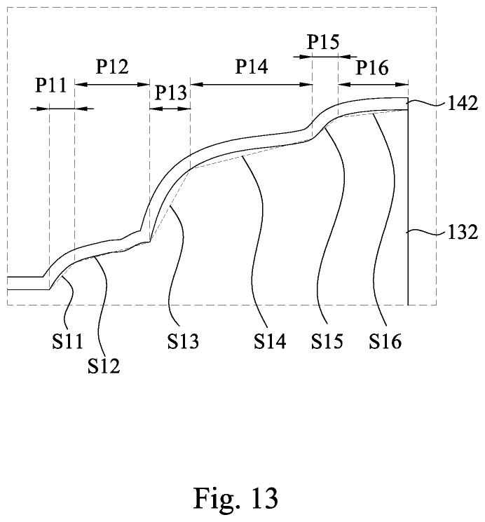

FIG. 12 illustrates a cross-section view of a display panel 100 in some other embodiments of the present disclosure. The display panel 100 in FIG. 12 is similar to the display panel 100 in FIG. 1. The difference is that the opening O1 of the sidewall of the first photosensitive material layer 132 of the display panel 100 in FIG. 12 further comprises a third portion P13, a fourth portion P14, a fifth portion P15 and a sixth portion P16. The first portion is the closest to the second electrode pad 118, and the sixth portion P16 is the farthest away from the second electrode pad 118. The first portion P11 is connected with the second portion P12, the second portion P12 is connected with the third portion P13, the third portion P13 is connected with the fourth portion P14, the fourth portion P14 is connected with the fifth portion P15 and fifth portion P15 is connected with the sixth portion P16 (see FIG. 13). FIG. 13 illustrates a profile of the first photosensitive material layer 132 of the display panel 100 in region M in FIG. 12. A third slope S13 of the third portion P13 of the sidewall of the opening O1 of the first photosensitive material layer 132 is greater than the second slope S12 of the second portion P12 of the sidewall of the opening O1 of the first photosensitive material layer 132 and a fourth slope S14 of the fourth portion P14 of the sidewall of the opening O1 of the first photosensitive material layer 132. A fifth slope S15 of the fifth portion P15 of the sidewall of the opening O1 of the first photosensitive material layer 132 is greater than the fourth slope S14 of the fourth portion P14 of the sidewall of the opening O1 of the first photosensitive material layer 132 and a sixth slope S16 of the sixth portion P16 of the sidewall of the opening O1 of the first photosensitive material layer 132. As a result, the slope of the first photosensitive material layer 132 may be reduced, such that the slope of the first transparent conductive layer 142 subsequently formed on the first photosensitive material layer 132 may be reduced. Therefore, the possibility of fracture of the first transparent conductive layer 142 may be reduced. In some embodiments, the first slope S11, the third slope S13 and the fifth slope S15 are greater than 1, and the second slope S12, the fourth slope S14 and the sixth slope S16 are less than 1. In some embodiments, the first slope S11, the third slope S13 and the fifth slope S15 are not greater than 1.2. The manufacturing method of the display panel 100 in FIG. 12 is similar to the manufacturing method of the display panel 100 in FIG. 1. The difference is the size of the slits and the distances between the slits of the first slit tone mask used for exposing the first photosensitive material layer. That is, the first photosensitive material layer 132 of the display panel 100 in FIG. 12 includes multiple staircase structures, such as three staircase structures, while the first photosensitive material layer 132 of the display panel 100 in FIG. 1 includes one staircase structure.

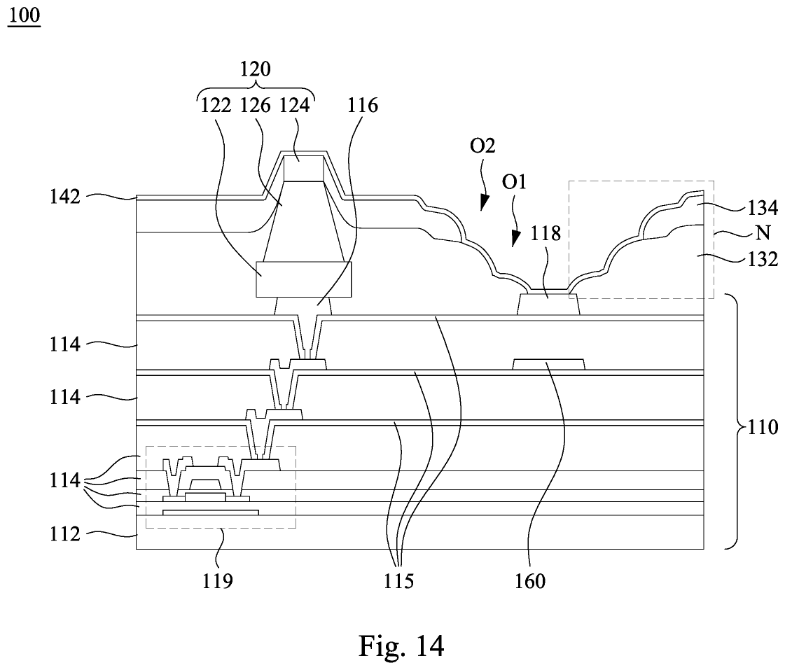

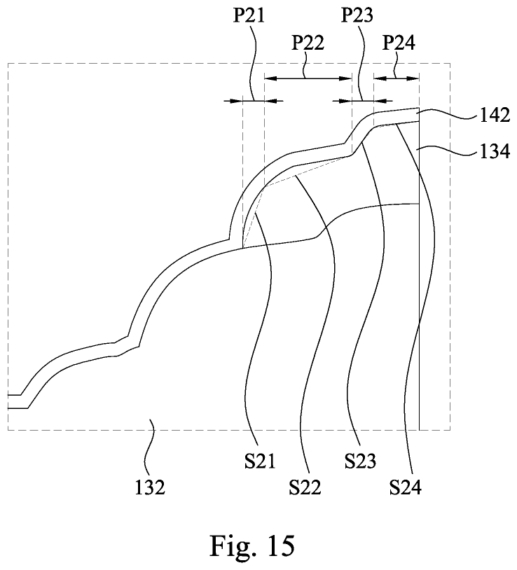

FIG. 14 illustrates a cross-section view of the display panel 100 in some other embodiments of the present disclosure. The display panel 100 in FIG. 14 is similar to the display panel 100 in FIG. 12. The difference is that the display panel 100 in FIG. 14 further includes the second photosensitive material layer 134. FIG. 15 illustrates a profile of the first photosensitive material layer 132 and the second photosensitive material layer 134 of the display panel 100 in region N in FIG. 14. The sidewall of the opening O2 of the second photosensitive material layer 134 includes a first portion P21, a second portion P22, a third portion P23 and a fourth portion P24. A first slope S21 of the first portion P21 of the sidewall of the opening O2 of the second photosensitive material layer 134 is greater than the second slope S22 of the second portion P22 of the sidewall of the opening O2 of the second photosensitive material layer 134. The second slope S22 of the second portion P22 of the sidewall of the opening O2 of the second photosensitive material layer 134 and a fourth slope S24 of the fourth portion P24 of the sidewall of the opening O2 of the second photosensitive material layer 134 are less than a third slope S23 of the third portion P23 of the sidewall of the opening O2 of the second photosensitive material layer 134. As a result, the slope of the second photosensitive material layer 134 may be reduced, such that the slope of the first transparent conductive layer 142 subsequently formed on the first photosensitive material layer 132 may be reduced. Therefore, the possibility of fracture of the first transparent conductive layer 142 may be reduced. In some embodiments, the first slope S21 and the third slope S23 are greater than 1, and the second slope S22 and the fourth slope S24 are less than 1. In some embodiments, the first slope S21 and the third slope S23 are not greater than 1.2. The manufacturing method of the display panel 100 in FIG. 14 is similar to the manufacturing method of the display panel 100 in FIG. 3. The difference is the size of the slits and the distances between the slits of the slit tone mask used for exposing the first photosensitive material layer and the second photosensitive material layer. That is, the second photosensitive material layer 134 of the display panel 100 in FIG. 14 also includes multiple staircase structures, such as two staircase structures.

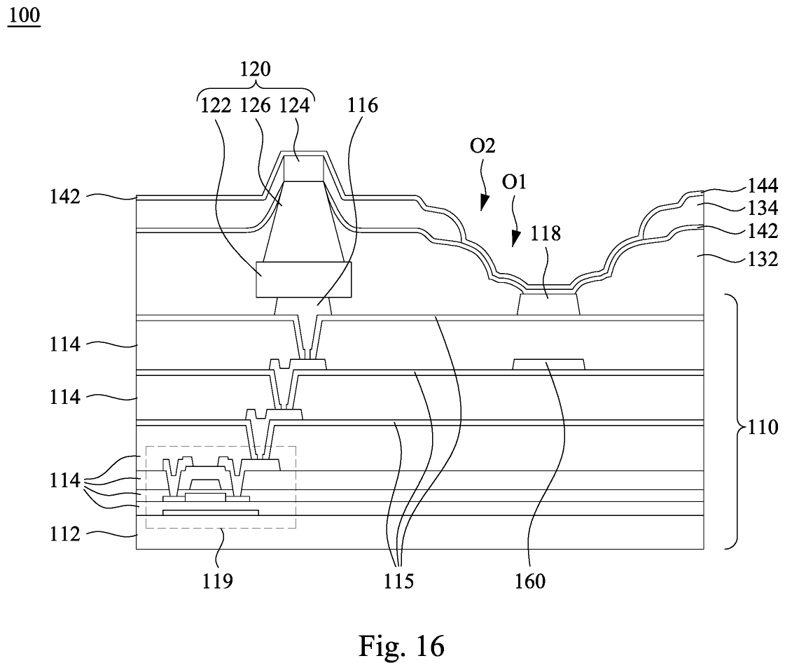

FIG. 16 illustrates a cross-section view of the display panel 100 in some other embodiments of the present disclosure. The display panel 100 in FIG. 16 is similar to the display panel 100 in FIG. 14. The difference is that the display panel 100 in FIG. 16 further includes a second transparent conductive layer 144. In the display panel 100 in FIG. 16, the first transparent conductive layer 142 is over the first photosensitive material layer 132 and in contact with the second electrode pad 118. The second photosensitive material layer 134 is over the first transparent conductive layer 142, and the second transparent conductive layer 144 is over the second photosensitive material layer 134 and the first transparent conductive layer 142. The material of the second transparent conductive layer 144 may be similar to or the same as the material of the first transparent conductive layer 142. The manufacturing method of the display panel 100 in FIG. 16 is also similar to the manufacturing method of the display panel 100 in FIG. 14. The difference is that the first transparent conductive layer 142 is formed over the first photosensitive material layer 132 before forming the second photosensitive material layer 134 during forming the display panel 100 in FIG. 16. Subsequently, the second photosensitive material layer 134 is formed over the first transparent conductive layer 142. Subsequently, the second transparent conductive layer 144 is formed over the second photosensitive material layer 134. The second transparent conductive layer 144 electrically connects the second electrode 124 of the light-emitting diode chip 120 and the second electrode pad 118 of the array substrate 110. When the display panel 100 includes the first transparent conductive layer 142 and the second transparent conductive layer 144 at the same time, the possibility of the light-emitting diode chip 120 being not working due to the fracture of the transparent conductive layer is reduced.

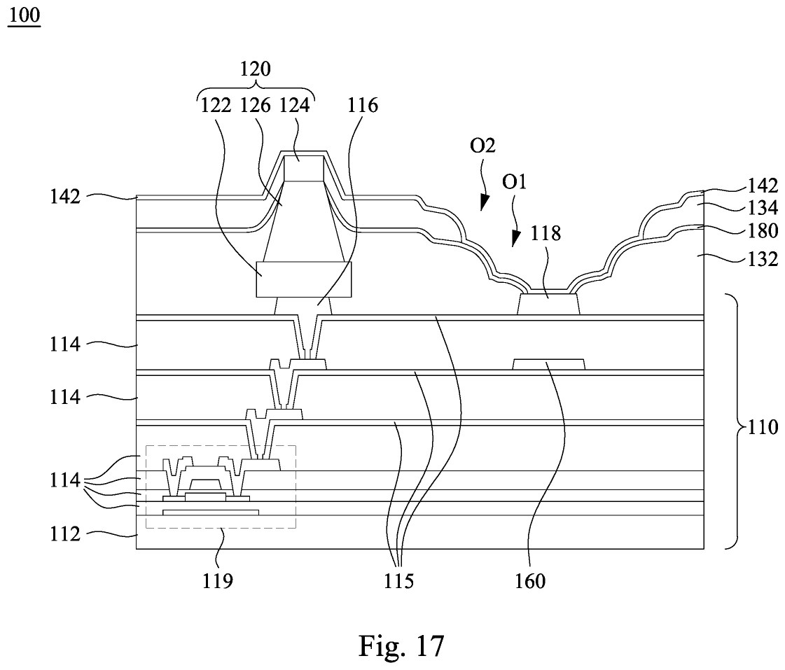

FIG. 17 illustrates a cross-section view of the display panel 100 in some other embodiments of the present disclosure. The display panel 100 in FIG. 17 is similar to the display panel 100 in FIG. 14. The difference is that the display panel 100 in FIG. 17 further includes a nitride layer 180 between the first photosensitive material layer 132 and the first transparent conductive layer 142. In some embodiments, the nitride layer 180 is further between the first photosensitive material layer 132 and the second photosensitive material layer 134. The manufacturing method of the display panel 100 in FIG. 17 is similar to the manufacturing method of the display panel 100 in FIG. 14. The difference is that the nitride layer 180 is formed over the first photosensitive material layer 132 before forming the first transparent conductive layer 142 during forming the display panel 100 in FIG. 17. Subsequently, the second photosensitive material layer 134 is formed over the nitride layer 180. Subsequently, the first transparent conductive layer 142 is formed over the second photosensitive material layer 134. When the display panel 100 includes the nitride layer 180, the possibility of the corrosion of the first transparent conductive layer 142, or the possibility of the fracture of the first transparent conductive layer 142 due to the uneven photosensitive material below is reduced.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A display panel, comprising:
an array substrate comprising:
a carrier board;
a dielectric layer stack over the carrier board;
a first electrode pad over the dielectric layer stack; and
a second electrode pad over the dielectric layer stack and adjacent to the first electrode pad, and the first electrode pad and the second electrode pad provide different potentials;
a light-emitting diode chip comprising a first electrode and a second electrode at opposite sides of the light-emitting diode chip, and the first electrode connected with the first electrode pad;
a first photosensitive material layer over the array substrate and surrounding the light-emitting diode chip, wherein the first photosensitive material layer comprises an opening exposing the second electrode pad, a sidewall of the opening of the first photosensitive material layer has a first portion and a second portion, a first slope of the first portion of the sidewall of the opening of the first photosensitive material layer is greater than a second slope of the second portion of the sidewall of the opening of the first photosensitive material layer, and a vertical projection of the first portion of the sidewall of the opening of the first photosensitive material layer on the array substrate is smaller than a vertical projection of the second portion of the sidewall of the opening of the first photosensitive material layer on the array substrate; and
a first transparent conductive layer over the first photosensitive material layer and electrically connecting the second electrode pad and the second electrode.

2. The display panel of claim 1, further comprising a second photosensitive material layer over the first photosensitive material layer and surrounding the light-emitting diode chip, wherein the second photosensitive material layer comprises an opening exposing the second electrode pad and a portion of the first photosensitive material layer, a sidewall of the opening of the second photosensitive material layer has a first portion and a second portion, a first slope of the first portion of the sidewall of the opening of the second photosensitive material layer is greater than a second slope of the second portion of the sidewall of the opening of the second photosensitive material layer.

3. The display panel of claim 2, wherein the first slope of the first portion of the sidewall of the opening of the first photosensitive material layer is greater than 1, and the second slope of the first portion of the sidewall of the opening of the first photosensitive material layer is less than 1.

4. The display panel of claim 3, wherein the first slope of the first portion of the sidewall of the opening of the first photosensitive material layer is less than 1.2.

5. The display panel of claim 2, wherein the first slope of the first portion of the sidewall of the opening of the second photosensitive material layer is greater than 1, and the second slope of the first portion of the sidewall of the opening of the second photosensitive material layer is less than 1.

6. The display panel of claim 5, wherein the first slope of the first portion of the sidewall of the opening of the second photosensitive material layer is less than 1.2.

7. The display panel of claim 2, wherein the sidewall of the opening of the first photosensitive material layer further has a third portion and a fourth portion, the second slope of the second portion and a fourth slope of the fourth portion of the sidewall of the opening of the first photosensitive material layer are less than a third slope of the third portion of the sidewall of the opening of the first photosensitive material layer.

8. The display panel of claim 2, wherein the sidewall of the opening of the second photosensitive material layer further has a third portion and a fourth portion, the second slope of the second portion and a fourth slope of the fourth portion of the sidewall of the opening of the second photosensitive material layer are less than a third slope of the third portion of the sidewall of the opening of the second photosensitive material layer.

9. A display panel, comprising:
an array substrate comprising:
a carrier board;
an active component over the carrier board;
a dielectric layer stack over the active component and the carrier board;
a first electrode pad over the dielectric layer stack and connected with the active component; and
a second electrode pad over the dielectric layer stack and adjacent to the first electrode pad;
a light-emitting diode chip comprising a first electrode and a second electrode at opposite sides of the light-emitting diode chip, and the first electrode connected with the first electrode pad;
a first photosensitive material layer over the array substrate and surrounding the light-emitting diode chip, wherein the first photosensitive material layer comprises an opening exposing the second electrode pad;
a first transparent conductive layer over the first photosensitive material layer and in contact with the second electrode pad;
a second photosensitive material layer over the first photosensitive material layer and surrounding the light-emitting diode chip, wherein the second photosensitive material layer comprises an opening exposing the second electrode pad and a portion of the first photosensitive material layer; and
a second transparent conductive layer over the second photosensitive material layer and the first transparent conductive layer.

10. The display panel of claim 9, further comprising a nitride layer between the first photosensitive material layer and the first transparent conductive layer.

11. The display panel of claim 9, wherein the first transparent conductive layer is between the first photosensitive material layer and the second photosensitive material layer.

12. The display panel of claim 9, wherein a sidewall of the opening of the first photosensitive material layer has a first portion and a second portion, the first portion is closer to the second electrode pad, the second portion is farther away from the second electrode pad, a first slope of the first portion of the sidewall of the opening of the first photosensitive material layer is greater than a second slope of the second portion of the sidewall of the opening of the first photosensitive material layer.

13. The display panel of claim 12, wherein the sidewall of the opening of the first photosensitive material layer further has a third portion and a fourth portion, the third portion is connected with the second portion, the third portion is connected with the third portion, a third slope of the third portion of the sidewall of the opening of the first photosensitive material layer is greater than the second slope of the second portion of the sidewall of the opening of the first photosensitive material layer and a fourth slope of the fourth portion of the sidewall of the opening of the first photosensitive material layer.

14. The display panel of claim 9, wherein the second photosensitive material layer comprises an opening exposing the second electrode pad and a portion of the first photosensitive material layer, a sidewall of the opening of the second photosensitive material layer has a first portion and a second portion, a first slope of the first portion of the sidewall of the opening of the second photosensitive material layer is greater than a second slope of the second portion of the sidewall of the opening of the second photosensitive material layer.

15. A method of manufacturing a display panel, comprising:
disposing a light-emitting diode chip over a array substrate, wherein the light-emitting diode chip comprises a first electrode and a second electrode at opposite sides of the light-emitting diode chip, and the first electrode is connected with a first electrode pad of the array substrate;
forming a first photosensitive material layer over the array substrate, and the first photosensitive material layer surrounding the light-emitting diode chip;
exposing the first photosensitive material layer by a first slit tone photomask;
developing the first photosensitive material layer, such that the first photosensitive material layer comprises an opening exposing a second electrode pad of the array substrate, a sidewall of the opening of the first photosensitive material layer has a first portion and a second portion, a first slope of the first portion of the sidewall of the opening of the first photosensitive material layer is greater than a second slope of the second portion of the sidewall of the opening of the first photosensitive material layer; and
forming a first transparent conductive layer over the first photosensitive material layer, the first transparent conductive layer electrically connected with the second electrode of the light-emitting diode chip and the second electrode pad of the array substrate.

16. The method of claim 15, wherein exposing the first photosensitive material layer by the first slit tone photomask comprises adjusting distances between slits of the first slit tone photomask.

17. The method of claim 15, wherein exposing the first photosensitive material layer by the first slit tone photomask comprises adjusting sizes of slits of the first slit tone photomask.

18. The method of claim 15, further comprising:
after forming the first transparent conductive layer, forming a second photosensitive material layer over the first transparent conductive layer and surrounding the light-emitting diode chip;
exposing the second photosensitive material layer by a second slit tone photomask;
developing the second photosensitive material layer, such that the second photosensitive material layer comprises an opening exposing the second electrode pad, a sidewall of the opening of the second photosensitive material layer has a first portion and a second portion, a first slope of the first portion of the sidewall of the opening of the second photosensitive material layer is greater than a second slope of the second portion of the sidewall of the opening of the second photosensitive material layer; and
forming a second transparent conductive layer over the second photosensitive material layer, the second transparent conductive layer electrically connected with the second electrode of the light-emitting diode chip and the second electrode pad of the array substrate.

19. The method of claim 18, wherein exposing the second photosensitive material layer by the second slit tone photomask comprises adjusting distances between slits of the second slit tone photomask.

20. The method of claim 18, wherein exposing the second photosensitive material layer by the second slit tone photomask comprises adjusting sizes of slits of the second slit tone photomask.
